(19) United States
(12) Patent Application Publication
(10) Pub. No.: US 2002/0142621 A1
(43) Pub. Date: Oct. 3, 2002

(54) VAPOR PHASE DEPOSITION OF UNIFORM AND ULTRATHIN SILANCES

(76) Inventor: YUCHUNG WANG, ALBANY, CA (US)

Correspondence Address: FISH AND RICHARDSON P.C., 2200 SAND HILL ROAD, SUITE 100, MENLO PARK, CA, 94025, US

(21) Appl. No.: 09/007,989

(22) Filed: Jan. 16, 1998

(51) Int. Cl. H01L 21/31

(52) U.S. Cl. 438/765

(57) ABSTRACT

A vapor-phase coating method forms a uniform and nanometer thick silanes on a silicon surface at ambient pressure using nitrogen as a carrier gas. A cleaned silicon wafer is placed in a chamber and flushed with dry nitrogen. As dry nitrogen is flushing through the chamber, a silanizing reagent such as alkyltrichlorosilane or alkyltrimethoxysilane is injected into the chamber and the nitrogen flushing is continued until the silanizing agent is depleted. The nitrogen gas serves as both a protecting medium and a diluent. The moisture free atmosphere yields a surface that is extremely smooth and without any detectable aggregates. The coatings and subsequent treatments are characterized with ellipsometry, scanning electron microscopy, contact angles, sum frequency generation (SFG) spectroscopy, and zeta potential in water. The method of deposition is particularly advantageous whenever it is necessary to coat irregular shapes or channels in microdevices, where liquids may have difficult access due to capillary forces.

### BACKGROUND

The present invention relates to vapor phase deposition, and more particularly to vapor phase deposition of silanes.

Uniform, conformal, and ultrathin (or monolayer) coatings on silicon based surfaces are desired for a number of applications. In the micromachining of microelectromechanical system (MEMS), a final hydrophobic coating on the device is needed to prevent adhesion of adjacent surfaces due to capillary forces in condensed water. Thus, a hydrophilic and uniform coating is desired for silicon based medical devices such as filters or capsules that are in contact with protein solutions to regulate hydrophilicity and minimize unspecific protein adsorption.

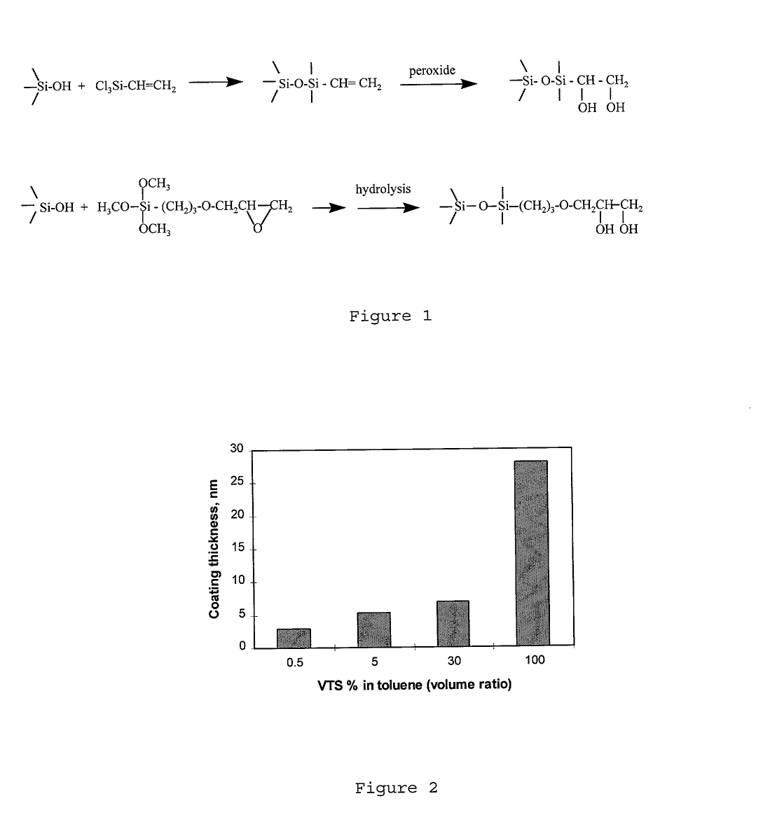

Currently, the predominant coating methods typically involve the assembly of a silane “monolayer” onto silicon surfaces in an organic solution. It is known that alcohol groups, being hydrophilic and neutral, can drastically reduce protein adsorption on the surface of contact lenses, glass membranes, and porous silica. To assemble a monolayer of alcohol groups onto a silicon filter surface for protein ultrafiltration, one step is to coat silicon with vinyltrichlorosilane (VTS) or γ-glycidoxy-propyltrimethoxysilane (GPTMS), then convert the vinyl or epoxide to alcohol groups. The chemical reactions between the silanol groups on silicon surface and the substituted silanes are shown in FIG. 1. Currently the predominant method is to assemble the so-called “monolayer” silane onto a silicon surface in an organic solution. Typical prototype molecules are alkyltrichlorosilanes (denoted as RSiCl₃) or alkyltrimethoxysilanes (denoted as RSi(OCH₃)₃), where R is any desired functional group to be introduced into the coating. However, trichlorosilanes are very sensitive to moisture. Even trace amounts of water in the organic solution or its environment could lead to polymerization. This causes the formation of multilayers with variable thicknesses, and submicron aggregates or islands on the silicon surface. To avoid this polymerization problem, an alternative method invokes the use of monochlorosilane, which is incapable of polymerization. However, monochlorosilane forms a less stable coating than alkyltrichlorosilane, which has three chlorine anchoring sites per molecule. Another method coats the silanes in a high vacuum. This approach increases the capital cost compared with solution coating.

### SUMMARY

A vapor-phase coating method forms a uniform and nanometer thick silanes on silicon surface at ambient pressure using nitrogen as a carrier gas. A cleaned silicon wafer is placed in a chamber and flushed with dry nitrogen. As dry nitrogen is flushing through the chamber, a silanizing reagent such as alkyltrichlorosilane is injected into the chamber and the nitrogen flushing is continued until the silanizing reagent is depleted. The nitrogen gas serves as both a protecting medium and a diluent.

Advantages of the invention include the following. The moisture free atmosphere yields a surface that is extremely smooth and without any detectable aggregates. The concentration of chlorosilane molecules in the vapor phase is at least three orders of magnitude lower than the solution coating approach. Hence, silane molecules are more regularly packed on the surface. A uniform coating of about 1 nm in thickness can be consistently achieved. The method of deposition is particularly advantageous whenever it is necessary to coat irregular shapes or channels in microdevices, where liquids may have difficult access due to capillary forces. No solvent is needed in the coating step or washing after the coating step. The process is applicable to a wide range of surfaces, including silicon based surfaces and metal oxide based surfaces.

### DESCRIPTION

Semiconductor grade p-type test wafers were cut into 1 cm×2 cm chips and cleaned in 2:1 sulfuric acid and 30% hydrogen peroxide (piranha) at 80° C. for 20 minutes. After rinsing with deionized water, the chips were dried by nitrogen and immediately used for coating. In solution coating, the chips were placed in scintillation vials and then toluene (solvent), vinyltrichlorosilane (VTS) or γ-glycidoxy-propyl-trimethoxysilane (GPTMS) were added to the vials. After mixing, the vials were sealed and stood for a period of time. The chips were rinsed with large amounts of solvent and dried. In vapor phase coating, cleaned chips were immediately transferred into a Teflon chamber. Dry nitrogen was run through the Teflon chamber for 10-15 minutes and the silanizing reagent was injected into the nitrogen stream at a certain temperature. Nitrogen flushing continued until the silanizing reagent was depleted from the chamber, when no silanizing reagent was detected at the exit of the chamber. All the chemicals used are available from Aldrich Chemicals, Inc.

The coating was characterized by ellipsometry for coating thickness, contact angles for wetting, and SEM (or AFM) for surface morphology. In the measurement by ellipsometry, the thickness was the average of at least 10 different spots. The standard deviation was typically ±2 Å for film thickness of around 1 nm. The refractive index of the coating was assumed to be 1.46. To characterize the coating composition, both VTS and GPTMS were deposited on silica in vapor phase and tested by sum frequency generation (SFG). To compare the change of surface charge, silicon wafers were ground into a slurry in water. After drying, the silicon powders were coated with VTS or GPTMS under the identical conditions as the coating of silicon wafers. The zeta potentials of the silicon slurry and the coated silicon powders were measured in deionized water.

1. Solution Coating with Vinyltrichlorosilane (VTS)

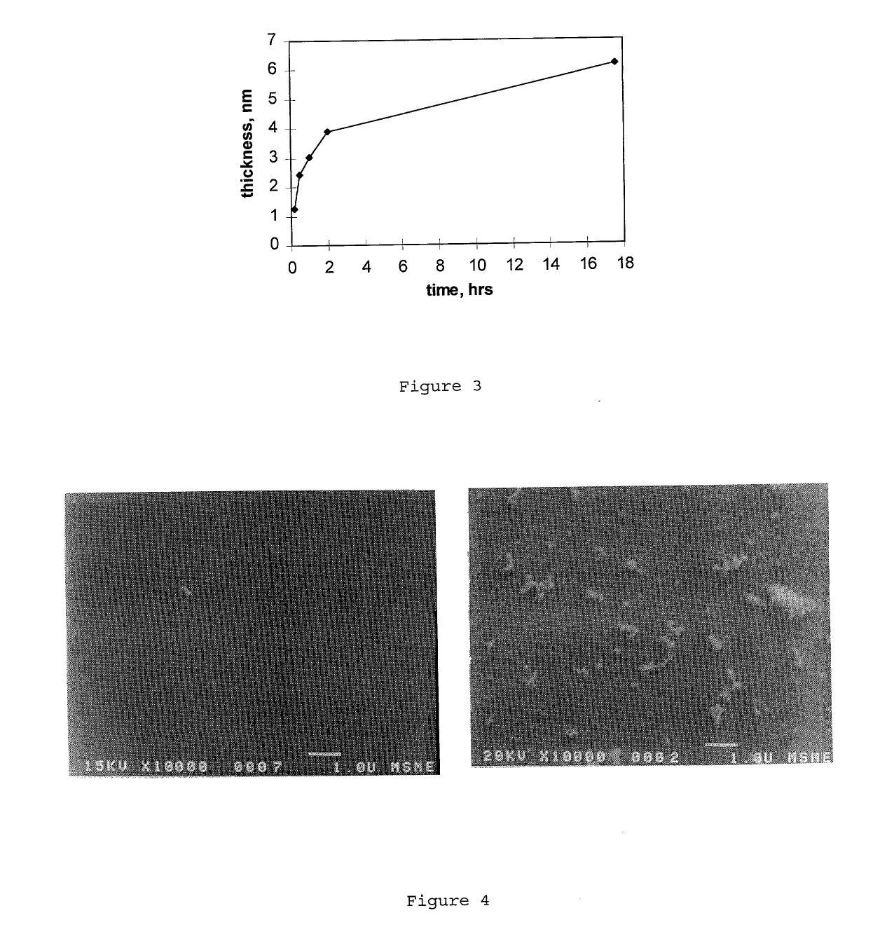

VTS is very reactive to silanol groups and water. Ideally in the absence of moisture VTS only reacts with the surface silanol groups to form a self assembled monolayer. In reality it is difficult to control the moisture to form only a monolayer. FIG. 2 and FIG. 3 show that the coating thickness increased with both VTS concentration and reaction time. These results indicate that multilayers were formed under such conditions. It may, however, be possible to obtain a “monolayer” by using very low concentrations and short contact time. Typical contact angles with water after VTS coating were about 90°. The contact angles and coating thickness did not change after immersion in water or dilute H₂SO₄ for a week. After cooking in 1:1 mixture of 30% H₂O₂ and concentrated H₂SO₄ for 10 minutes, the contact angle dropped to almost zero but the coating thickness did not change appreciably (a few angstroms). This indicates that the coating was stable and the vinyl groups were oxidized to hydrophilic groups.

As a comparison, silicon was coated with 5-10% monochlorotrimethylsilane-toluene and the coating thickness was always less than 5 Å and contact angle ˜90°, indicative of a real monolayer. Similarly, the thickness of monochlorovinyl-dimethylsilane coating was also below 5 Å, as shown in Table 1. This confirms the polymerization mechanism of VTS, leading to multilayers due to trace moisture. The coating samples were also examined with SEM. Some polymeric sub-micron aggregates are seen in FIG. 4(a) while the coating with monochlorosilanes has a smooth surface in FIG. 4(b). In addition, GPTMS was coated onto silicon wafers in toluene solution and multilayers also formed due to polymerization or physical adsorption.

TABLE 1
Coating of silicon with monochlorovinyldimethylsilane-
toluene solution for 20 hours at 20° C.

| % | | |
|---|---|---|
| concentration | | |
| (volume | coating | contact |
| ratio) | thickness, Å | angles |
| 0.5 | 1.2 ± 1.6 | 88 |
| 1.0 | 4.2 ± 1.7 | 86 |
| 2.0 | 4.4 ± 2.6 | 87 |
| 4.0 | 2.4 ± 1.4 | 86 |

2. Vapor Phase Coating of VTS and GPTMS

Solution coating as described above is not appropriate for silicon filter channel surface modification because of the multilayers and aggregates on the silicon surface. These problems are solved by changing the coating media from solution to vapor phase. Vapor phase coating eliminates the solution coating problems and possesses the following advantages:

1. Easy control of moisture level and avoidance of the aggregates or multilayers.

2. Incorporation in the standard filter testing protocol which requires a nitrogen pass-through test.

3. Ease of vapor access to any irregular channels where the access of liquid is limited by capillary forces.

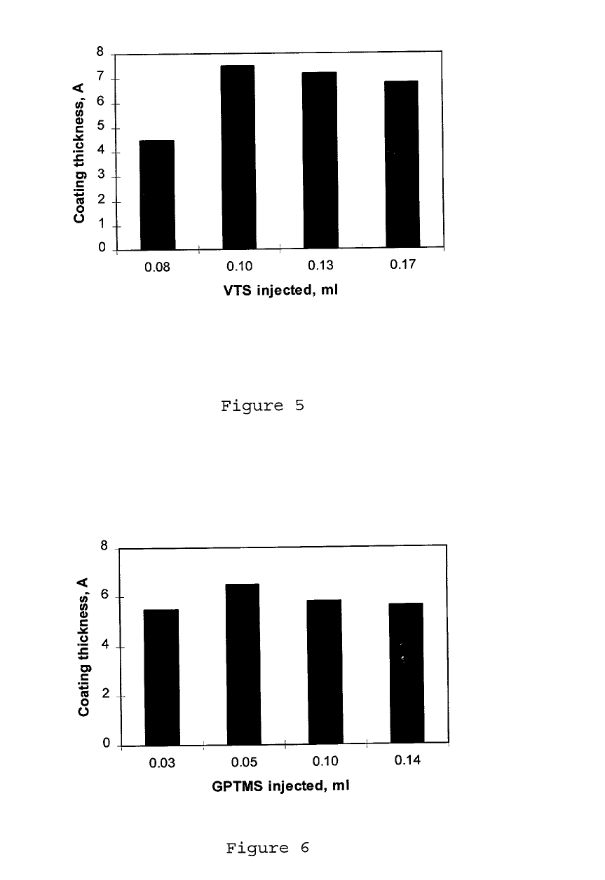

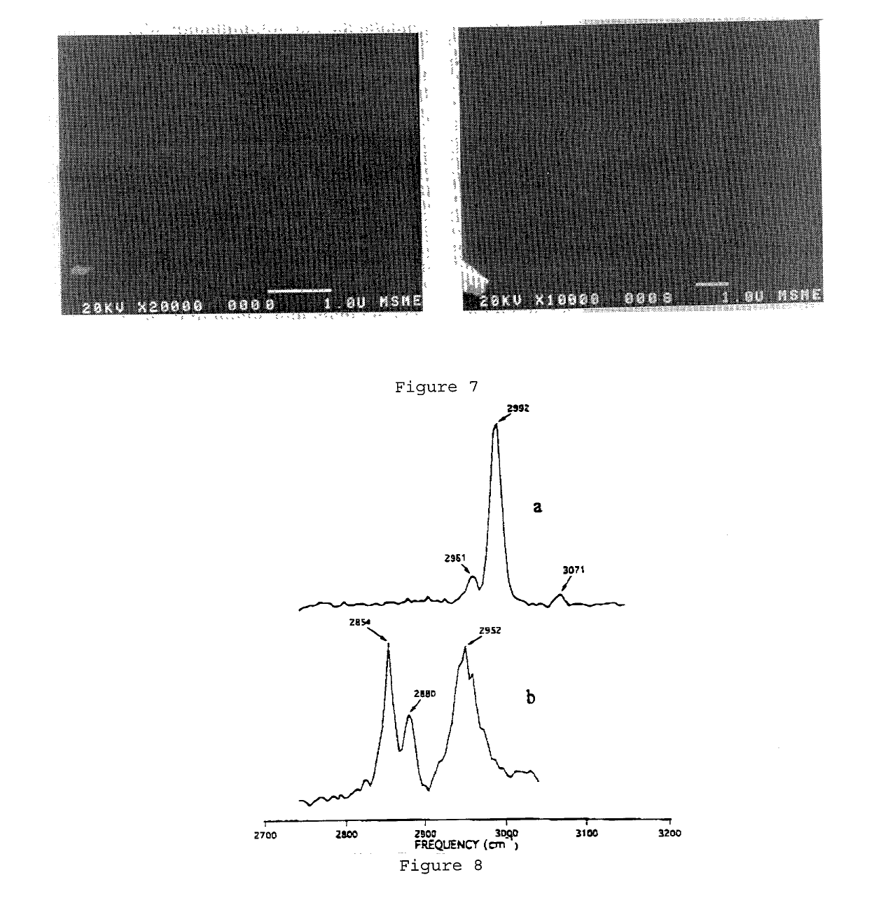

4. No solvent is used and thus contamination is minimized. VTS has a high vapor pressure at room temperature and the vapor phase coating was conducted at room temperature. After the vapor phase coating with VTS, the contact angle of the wafer was 80˜90°. GPTMS has a lower vapor pressure and is less reactive than VTS. The temperature for GPTMS coating was chosen to be 90˜100° C. The contact angle after GPTMS coating was around 60°. As seen in FIG. 5 and FIG. 6, the thickness of both coating was typically close to 1 nm. As observed by SEM in FIG. 7, no aggregate is found on the wafer surface.

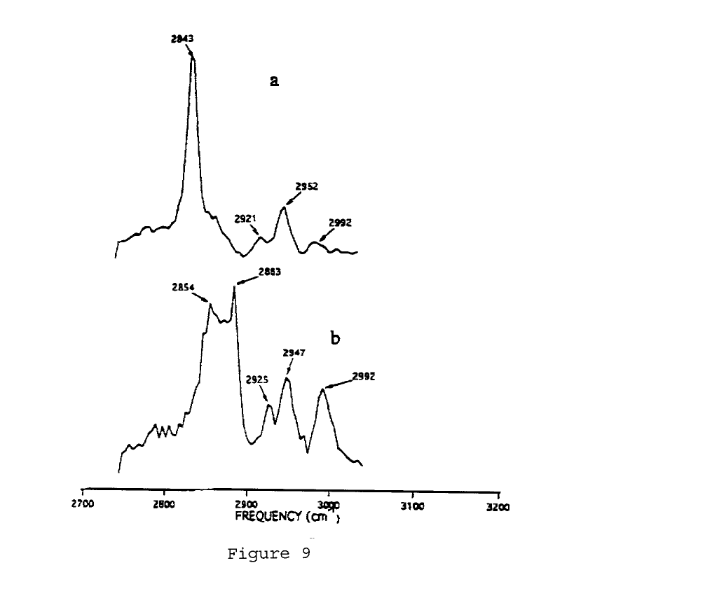

The coating composition was characterized with SFG. Silicon is a semiconductor and has a strong background absorption at the wavelength of interest. Therefore VTS and GPTMS were deposited onto silica glass surface in vapor phase. The spectra of VTS coating and GPTMS coating are shown in FIG. 8 and FIG. 9. The vinyl group in VTS coating is clearly seen at about 3071 and 2992 cm⁻¹. After the oxidation, CH₃ and CH₂ can be seen, which seems to indicate ketone as well as diol in the coating. The strong absorption at 2843 and 2952 cm⁻¹ correspond to the —CH₂— stretching in GPTMS. More complex peaks appear in the GPTMS coating after the hydrolysis and further characterization is in progress.

3. Surface Charge before and after the Coating

To further probe the surface properties of the coating, silicon wafers were ground into a slurry with deionized water. Following the identical conditions of the silicon wafer coating, the fine silicon particles were dried, coated in 0.5% VTS-toluene solution, and further oxidized in hot solution of H₂O₂+H₂SO₄. The zeta potential of the fine particles in deionized water was measured at each stage. The results are listed in Table 2.

TABLE 2
ζ potential of fine silicon particles in water before
and after solution coating

| | | ζ potential, mV |
|---|---|---|
| sample | | (average of 10 |
| name | sample treatment | measurements) |
| A | silicon slurry (suspension) by | −32.5 ± 5.0 |
| | grinding Si wafers in water | |
| B | A was dried, cleaned in hot | −32.0 ± 5.6 |
| | solution of 1:2 H₂O₂/H₂SO₄, then | |
| | washed to neutral | |
| C | B was dried, then immersed in 0.5% | −27.0 ± 4.8 |
| | VTS-toluene for 1 hour. Particles | |
| | were hydrophobic | |
| D | C was cooked in 1:1 H₂O₂/H₂SO₄ for | 27.3 ± 4.0 |
| | 20 minutes. Particles were | |
| | hydrophilic | |

Sample A shows that silicon surface exposed to water or air is negatively charged due to the ionization of the surface silanol groups. Sample B indicates that the strong oxidation environment did not change the surface charge. By comparing the coating conditions for sample C and the coating conditions in FIG. 3, it can be inferred that sample C should have been coated with at least one monolayer. However, sample C was still negatively charged due to the new silanol groups on the coating surface. This reflects the disorder of the coating structure by solution coating. Sample D was turned hydrophilic from sample C but had essentially the same surface charge as sample C. This suggests that the vinyl group was oxidized to neutral and hydrophilic groups such as diol.

The slurry was also coated with VTS and GPTMS in vapor phase and zeta potential was measured as shown in Table 3.

TABLE 3
ζ potential of fine silicon particles in water before
and after vapor phase coating.

| | | ζ potential, mV |
|---|---|---|
| sample | | (average of 10 |
| name | sample treatment | measurements) |
| X | silicon slurry (suspension) by | −28.0 ± 3.5 |
| | grinding Si wafers in water, then | |
| | dried at 90° C. for 3 hours | |
| Y | sample X was coated in VTS vapor at | −14.0 ± 2.4 |
| | 23° C. for 2 hours | |
| Z | sample X was coated in GPTMS vapor | 5.0 ± 2.0 |
| | at 97° C. for 2 hours | |

The zeta potential was greatly reduced by VTS vapor phase coating, but the surface was still negatively charged. In contrast, the surface after GPTMS vapor phase coating was almost neutral. This indicates that the surface is better covered by the longer chains in GPTMS than vinyl groups in VTS coating.

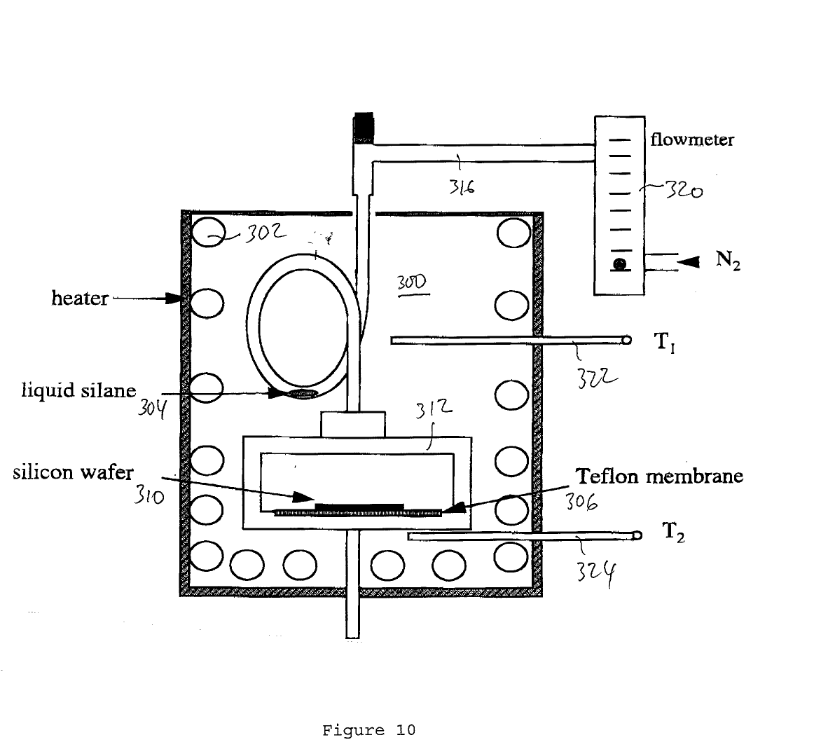

Referring now to FIG. 10, an apparatus for performing vapor phase coating is shown. The apparatus has a plurality of heaters 302 mounted around the perimeter of a processing chamber 300. Preferably, heating coils of the heater 302 are wound more densely at the bottom to provide a slight temperature gradient at the bottom of the chamber 300 to avoid any vapor condensation on the surface. A cleaned silicon wafer 310 is transferred into a teflon chamber 312. Nitrogen from a gas cylinder passes through a desiccant tube (not shown) and a gas flow meter 320 to enter the teflon chamber 312. The nitrogen finally encounters a teflon membrane 306 at the bottom of the chamber 312. Both the tubing 314 and the chamber 312 are made of teflon such that they are resistant to any chemical attacks. Depending on the reaction temperature needed, the heater 302 inside a glass cylinder is turned on while nitrogen is running. The heater 302 is connected with a thermal couple or a thermal-set (not shown) such that the temperature can be controlled. When the system is stabilized (typically within 20 minutes), 0.1 ml of substituted trichlorosilane or substituted trimethoxysilane is injected from the top port which is sealed by silicone elastomer. The temperature is usually below the boiling point of the reactants, thus a liquid droplet stays at the bending part of the tubing. The reactant's vapor is picked up by the running nitrogen and coats the silicon surface. The coating thickness is determined by the surface reaction. The apparatus of FIG. 10 operates in an absence of moisture to allow only a monolayer to be coated on the surface. This mimics a coating of the silicon filter surface. Any silicon based devices with small channels may be coated in this manner.

Hence, a solution coating with substituted trichlorosilane or trimethoxysilane results in multilayers and polymeric aggregates on silicon surface due to trace water. A uniform and ultrathin silane coating can be obtained by vapor phase coating using nitrogen as a carrier gas, which requires less stringent conditions and would be more compatible with micromachined silicon devices. The negative surface charge may be effectively eliminated by GPTMS vapor phase coating at 90 to 100° C.

While the invention has been shown and described with reference to an embodiment thereof, those skilled in the art will understand that the above and other changes in form and detail may be made without departing from the spirit and scope of the following claims.

What is claimed is:

1. A method for forming uniform and ultrathin silanes on a silicon surface at ambient pressure, comprising:
placing a cleaned silicon wafer in a chamber;
flushing the chamber with dry nitrogen;
injecting a silanizing reagent into the chamber; and
continuing the nitrogen flushing until the chamber is substantially free of the silanizing agent.

2. The method of claim 1, wherein the silanizing reagent is alkyltrichlorosilane.

3. The method of claim 1, wherein the silanizing reagent is alkyltrimethoxysilane.

4. The method of claim 1, wherein the chamber has a bottom portion, further comprising maintaining a temperature gradient at the bottom to avoid vapor condensation.
